(19) United States
(12) Patent Application Publication
(10) Pub. No.: US 2026/0075704 A1
(43) Pub. Date: Mar. 12, 2026

(54) ELECTRONIC DEVICE

(71) Applicant: PEGATRON CORPORATION, TAIPEI CITY (TW)

(72) Inventors: Chih-Wei Liao, Taipei City (TW); Huan-Chia Chang, Taipei City (TW); Chao-Hsu Wu, Taipei City (TW); Hau Yuen Tan, Taipei City (TW); Tsung-Chi Tsai, Taipei City (TW); Ming-Huang Chen, Taipei City (TW)

(73) Assignee: PEGATRON CORPORATION, TAIPEI CITY (TW)

(21) Appl. No.: 19/186,411

(22) Filed: Apr. 22, 2025

(30) Foreign Application Priority Data
Sep. 11, 2024 (TW) 113134433

(51) Int. Cl. H05K 1/02; H01Q 1/22; H01Q 7/00

(52) U.S. Cl. CPC H05K 1/0237; H01Q 1/2266; H01Q 7/00; H05K 2201/0707; H05K 2201/09827; H05K 2201/10098; H05K 2201/10371; H05K 2201/10553

(57) ABSTRACT

An electronic device includes a motherboard, a metal shielding cover, a near field communication (NFC) antenna module, and a shielding member. The metal shielding cover covers one side of the motherboard and includes a top surface away from the motherboard and an accommodating groove recessed in the top surface. The near field communication antenna module is disposed in the accommodating groove, and the near field communication antenna module is signal-connected to the motherboard. The shielding member is disposed on the top surface and includes a sensing area corresponding to the near field communication antenna module. The sensing area includes multiple through holes and a support structure located between the through holes.

### CROSS-REFERENCE TO RELATED APPLICATION

This application claims the priority benefit of Taiwan application serial no. 113134433, filed on Sep. 11, 2024. The entirety of the above-mentioned patent application is hereby incorporated by reference herein and made a part of this specification.

### BACKGROUND

### Technical Field

The disclosure relates to an electronic device, and more particularly to an electronic device having a near field communication antenna module.

### Description of Related Art

With the advancement of technology, electronic devices are becoming thinner and more multifunctional. Some electronic devices are capable of contactless point-to-point data transmission, which increases the convenience of use. How to provide good contactless point-to-point data transmission while taking the overall thickness into consideration is the research goal in the art.

### SUMMARY

The disclosure provides an electronic device with a near field communication antenna module that may provide a good contactless point-to-point data transmission function without affecting an overall thickness.

An electronic device of the disclosure includes a motherboard, a metal shielding cover, a near field communication (NFC) antenna module, and a shielding member. The metal shielding cover is disposed on one side of the motherboard and includes a top surface away from the motherboard and an accommodating groove recessed in the top surface. The near field communication (NFC) antenna module is disposed in the accommodating groove, and the near field communication antenna module is signal-connected to the motherboard. The shielding member is disposed on the top surface and includes a sensing area corresponding to the near field communication antenna module. The sensing area includes multiple through holes and a support structure located between the through holes.

In an embodiment of the disclosure, the accommodating groove gradually expands from a side away from the top surface to a side adjacent to the top surface, and the near field communication antenna module is lower than the top surface of the metal shielding cover.

In an embodiment of the disclosure, the accommodating groove includes a bottom surface and multiple inclined surfaces, an included angle θ is between any one of the inclined surfaces and a normal direction of the bottom surface, a height of the metal shielding cover is H, a width of the near field communication antenna module is W, and arctan[H/(W/2)]≤θ≤arctan[H/(W/4)].

In an embodiment of the disclosure, the accommodating groove includes a bottom surface and multiple inclined surfaces, an included angle θ is between any one of the inclined surfaces and a normal direction of the bottom surface, and 10°≤θ≤30°.

In an embodiment of the disclosure, the near field communication antenna module includes a first loop set and a second loop set located on different planes and having overlapping projections, and each of the first loop set and the second loop set includes at least one loop.

In an embodiment of the disclosure, the near field communication antenna module includes multiple loops located on a same plane.

In an embodiment of the disclosure, the support structure includes a first connection bar and a second connection bar crossing the sensing area and interlaced with each other, and the through holes are separated by the first connection bar and the second connection bar.

In an embodiment of the disclosure, the sensing area is a rectangle, the first connection bar connects midpoints of two long sides of the rectangle, and the second connection bar connects midpoints of two short sides of the rectangle.

In an embodiment of the disclosure, the sensing area is a rectangle, the first connection bar connects two opposite endpoints of the rectangle, and the second connection bar connects other two opposite endpoints of the rectangle.

In an embodiment of the disclosure, an area of the through holes accounts for more than 90% of an area of the sensing area.

In an embodiment of the disclosure, the electronic device further includes a touch display layer and a metal back cover. The touch display layer is disposed on the shielding member. The motherboard is located between the metal back cover and the metal shielding cover.

Based on the above, in the electronic device of the disclosure, the accommodating groove recessed in the top surface is formed on the metal shielding cover for covering the motherboard, and the near field communication antenna module is disposed in the accommodating groove. Since the metal shielding cover separates the motherboard and the near field communication antenna module, the metal shielding cover may effectively shield the influence of parts on the motherboard on the near field communication antenna module, thereby improving the performance of the near field communication antenna module. In addition, the shielding member is disposed on the top surface of the metal shielding cover and includes the sensing area corresponding to the near field communication antenna module. The through holes of the sensing area may allow a radiation signal of the near field communication antenna module to pass through, so as to perform contactless point-to-point data transmission. In addition, the support structure between the through holes may maintain the overall structural strength of the sensing area while providing the through holes for the radiation signal to pass through.

### BRIEF DESCRIPTION OF THE DRAWINGS

FIG. 1 is a partial cross-sectional schematic diagram of an electronic device according to an embodiment of the disclosure.

FIG. 2A is a schematic diagram of a first surface of a near field communication antenna module of FIG. 1.

FIG. 2B is a schematic diagram of a second surface of the near field communication antenna module of FIG. 1.

FIG. 3 is a schematic diagram of a first surface of a near field communication antenna module according to another embodiment of the disclosure.

FIG. 4 is a schematic diagram of a shielding member of FIG. 1.

FIG. 5 is a schematic diagram of a shielding member according to another embodiment of the disclosure.

### DESCRIPTION OF THE EMBODIMENTS

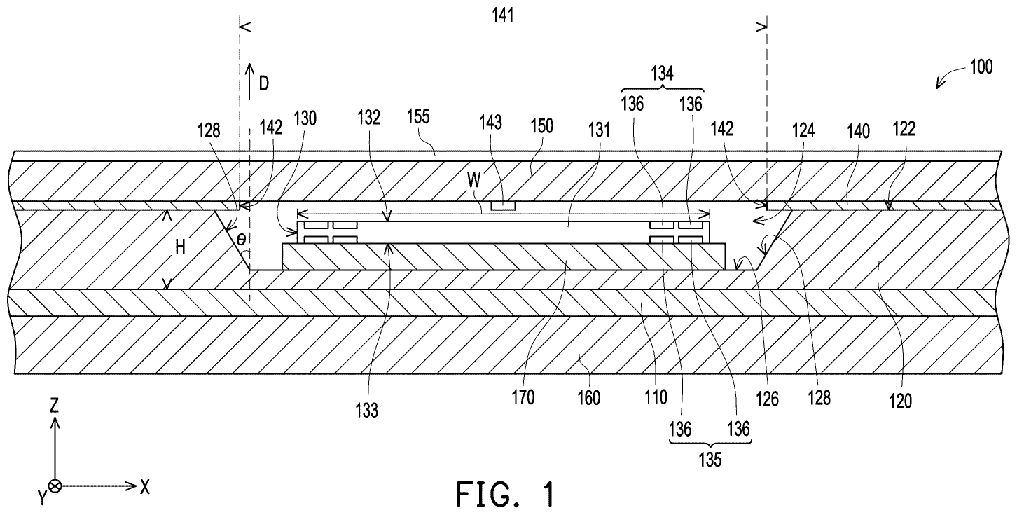

FIG. 1 is a partial cross-sectional schematic diagram of an electronic device according to an embodiment of the disclosure. Please refer to FIG. 1. An electronic device 100 of the embodiment is, for example, a tablet computer or a mobile phone, but the type of the electronic device 100 is not limited thereto. The electronic device 100 includes a motherboard 110, a metal shielding cover 120, a near field communication (NFC) antenna module 130, and a shielding member 140.

The metal shielding cover 120 covers one side of the motherboard 110. It should be noted that FIG. 1 is only for illustration and does not show parts on the motherboard 110. The metal shielding cover 120 actually has an internal space. The parts on the motherboard 110 are located in the internal space of the metal shielding cover 120. The metal shielding cover 120 may provide electromagnetic protection. FIG. 1 simply illustrates the positional relationship between the metal shielding cover 120 and the motherboard 110.

The metal shielding cover 120 includes a top surface 122 away from the motherboard 110 and an accommodating groove 124 recessed in the top surface 122. The near field communication antenna module 130 is disposed in the accommodating groove 124 of the metal shielding cover 120. In the embodiment, the working frequency band of the near field communication antenna module 130 is, for example, 13.56 MHz, but not limited thereto.

In the embodiment, the electronic device 100 forms the accommodating groove 124 recessed in the top surface 122 on the metal shielding cover 120 for covering the motherboard 110. The near field communication antenna module 130 is disposed in the accommodating groove 124. Since the metal shielding cover 120 separates the motherboard 110 and the near field communication antenna module 130, the metal shielding cover 120 may effectively shield the influence of the parts on the motherboard 110 on the near field communication antenna module 130, thereby improving the performance of the near field communication antenna module 130.

In addition, in the embodiment, the near field communication antenna module 130 is lower than the top surface 122 of the metal shielding cover 120. Therefore, the near field communication antenna module 130 does not increase the thickness of the electronic device 100. In addition, since the top surface 122 of the metal shielding cover 120 is higher than the near field communication antenna module 130, such a design can effectively eliminate the influence of eddy current on magnetic flux, thereby improving the performance of the near field communication antenna module 130.

In addition, a ferrite sheet 170 is attached below the near field communication antenna module 130. The ferrite sheet 170 is disposed in the accommodating groove 124 and also does not affect the thickness of the electronic device 100.

As can be seen from FIG. 1, the accommodating groove 124 of the metal shielding cover 120 gradually expands from a side away from the top surface 122 to a side adjacent to the top surface 122 (from the bottom to the top of FIG. 1). Specifically, the accommodating groove 124 includes a bottom surface 126 and multiple inclined surfaces 128, and the inclined surfaces 128 are inclined toward the shielding member 140. The accommodating groove 124 expanding toward the top surface 122 may prevent the metal shielding cover 120 from blocking the radiation of the near field communication antenna module 130, thereby further improving the extent of coverage of a radiation signal of the near field communication antenna module 130.

In a preferred embodiment, an included angle θ is between any one of the inclined surfaces 128 and a normal direction D of the bottom surface 126, the height of the metal shielding cover 120 is H, the width of the near field communication antenna module 130 is W, and arctan[H/(W/2)]≤θ≤arctan[H/(W/4)]. Through experiments, when the included angle θ is within the range, the near field communication antenna module 130 may have improved radiation power. In a preferred embodiment, the included angle θ is within the range of 10°≤θ≤30°. Of course, the range of the included angle θ is not limited to the above.

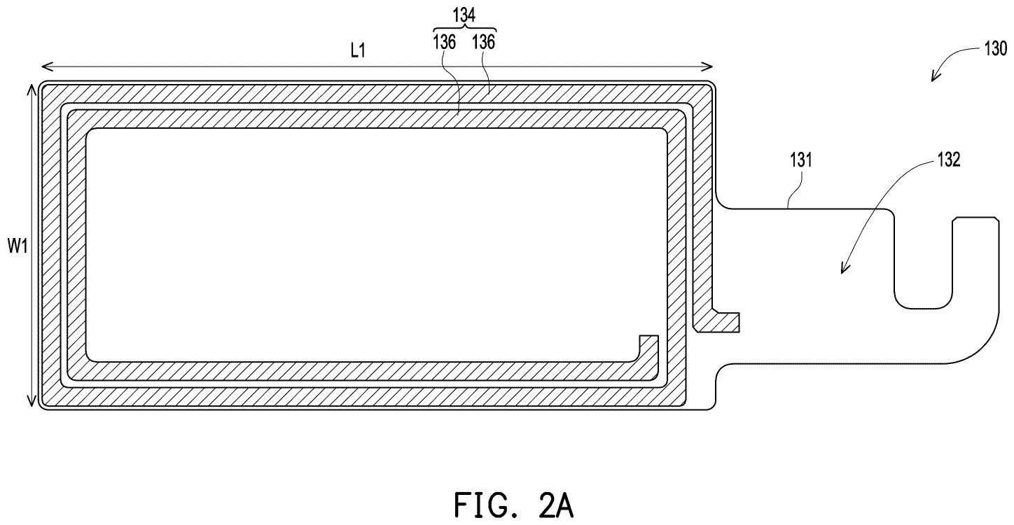

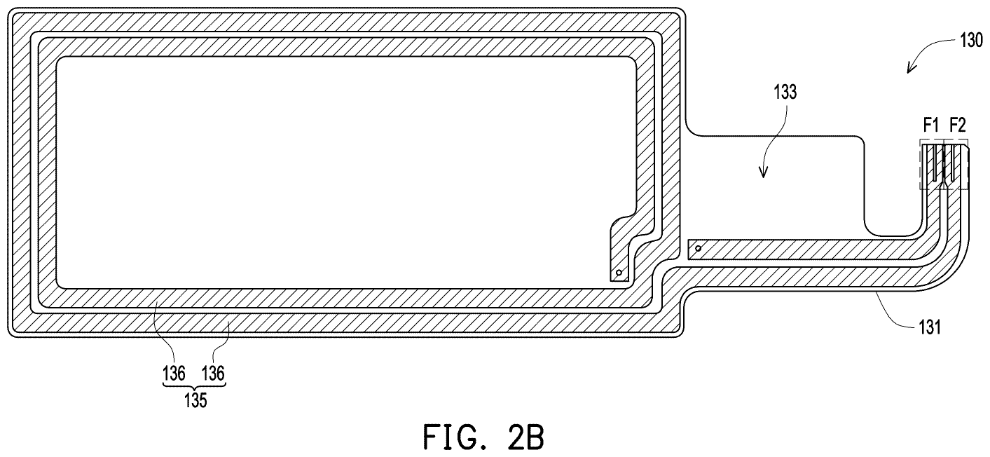

FIG. 2A is a schematic diagram of a first surface of a near field communication antenna module of FIG. 1. FIG. 2B is a schematic diagram of a second surface of the near field communication antenna module of FIG. 1. Please refer to FIG. 1, FIG. 2A, and FIG. 2B. In the embodiment, the near field communication antenna module 130 includes a first loop set 134 and a second loop set 135 located on different planes and having overlapping projections. Each of the first loop set 134 and the second loop set 135 includes at least one loop 136.

Specifically, in the embodiment, the near field communication antenna module 130 includes an insulating layer 131. The insulating layer 131 includes a first surface 132 (FIG. 2A) and a second surface 133 (FIG. 2B) opposite to each other. The first loop set 134 is located on the first surface 132, and the second loop set 135 is located on the second surface 133. In the embodiment, the first loop set 134 includes two loops 136, and the second loop set 135 includes two loops 136. Of course, the number and the configuration positions of the loops 136 are not limited thereto.

In the embodiment, a length L1 of the first loop set 134 is 37 mm and a width W1 is 18 mm, which are the same as the size of the second loop set 135. The values of the length L1 and the width W1 are not limited thereto. In addition, in the embodiment, the near field communication antenna module 130 is signal-connected to the motherboard 110 through pins F1 and F2 (FIG. 2B). Of course, the form of the near field communication antenna module 130 is not limited thereto.

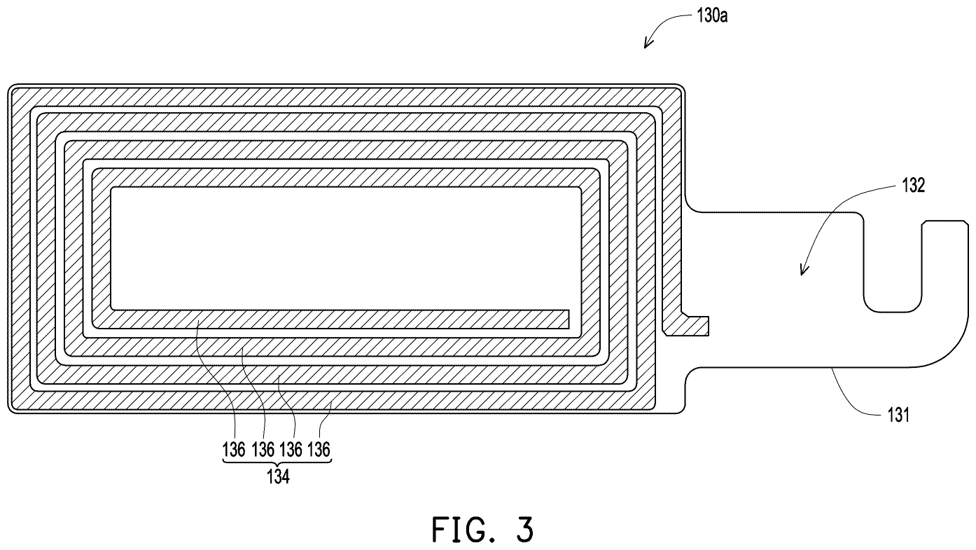

FIG. 3 is a schematic diagram of a first surface of a near field communication antenna module according to another embodiment of the disclosure. Please refer to FIG. 3. The main difference between a near field communication antenna module 130a of FIG. 3 and the near field communication antenna module 130 of FIG. 1 is that in the embodiment, the near field communication antenna module 130a includes multiple loops 136 located on the same plane. Specifically, the near field communication antenna module 130a is only provided with the first loop set 134 on the first surface 132, and the second surface 133 is not provided with any loop 136. The first loop set 134 includes four loops 136 as an example, but not limited thereto.

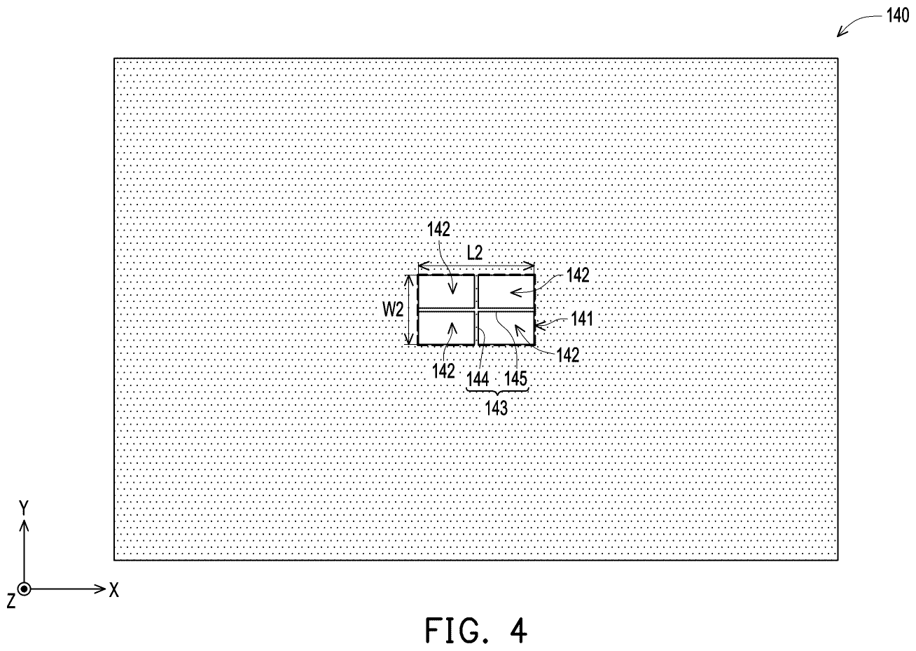

FIG. 4 is a schematic diagram of the shielding member of FIG. 1. Please refer to FIG. 1 and FIG. 4. In the embodiment, the shielding member 140 is disposed on the top surface 122 of the metal shielding cover 120 and may be made of a metallic material. The shielding member 140 includes a sensing area 141 corresponding to the near field communication antenna module 130. A length L2 of the sensing area 141 is approximately 47 mm, and a width W2 is approximately 28 mm, but not limited thereto.

The sensing area 141 includes multiple through holes 142 and a support structure 143 located between the through holes 142. The through holes 142 of the sensing area 141 may allow a radiation signal of the near field communication antenna module 130 to pass through, so as to perform contactless point-to-point data transmission.

As shown in FIG. 4, the area of the through holes 142 accounts for more than 90% of the area of the sensing area 141 to have a high perforation rate, thereby increasing a reading distance of the electronic device 100 for sensing an external device (for example, a card, not shown).

In the embodiment, the support structure 143 includes a first connection bar 144 and a second connection bar 145 crossing the sensing area 141 and interlaced with each other. In the embodiment, the sensing area 141 is a rectangle, the first connection bar 144 connects midpoints of two long sides of the rectangle, and the second connection bar 145 connects midpoints of two short sides of the rectangle. The through holes 142 are separated by the first connection bar 144 and the second connection bar 145. Each of the through holes 142 is rectangular, and the through holes 142 form a shape similar to a 2×2 matrix as a whole. Of course, the configuration of the through holes 142 is not limited thereto.

In the embodiment, the shielding member 140 is formed by punching the through holes 142 on a metal plate. The arrangement of the through holes 142 is, for example, a rectangular hole parallel type. Of course, in other embodiments, the arrangement of the through holes 142 may also be a 30-degree staggered type, a 45-degree staggered type, a 90-degree parallel type, an oblong hole staggered type, an oblong hole parallel type, a square hole staggered type, a square hole parallel type, a hexagonal 60-degree staggered type, or a rectangular hole staggered type. The arrangement of the through holes 142 is not limited to the above.

In addition, the support structure 143 between the through holes 142 may maintain the overall structural strength of the sensing area 141 of the shielding member 140, which helps to improve the horizontal waviness of the shielding member 140 without affecting the usage experience of a stylus. Under the premise of not affecting the sensing performance of the near field communication antenna module 130, magnetic field lines of the near field communication antenna module 130 in the internal space of the device can allow smooth transmission of electromagnetic signals with the nearby external device (for example, the card) through near field coupling. Therefore, the near field communication antenna module 130 may implement long reading distance and wide coverage. The reading distance between the electronic device 100 and the external device may reach more than 15 mm and meet the field strength specification requirements of the NFC Forum.

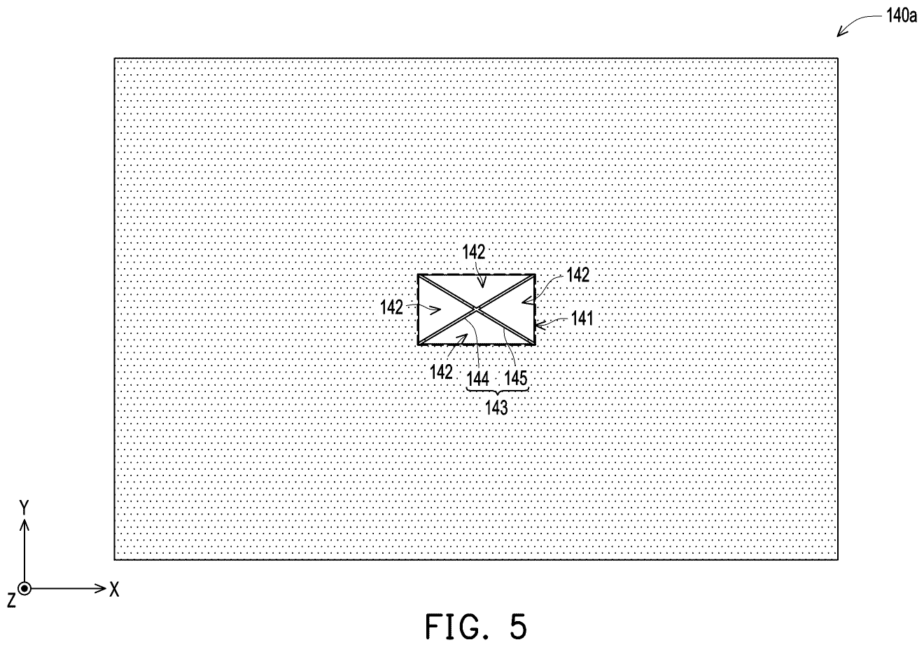

FIG. 5 is a schematic diagram of a shielding member according to another embodiment of the disclosure. Please refer to FIG. 5. The main difference between a shielding member 140a of FIG. 5 and the shielding member 140 of FIG. 4 is that in the embodiment, the first connection bar 144 connects two opposite endpoints of the rectangle, and the second connection bar 145 connects the other two opposite endpoints of the rectangle. Each of the through holes 142 is triangular. Of course, the shape of the through hole 142 and the form of the support structure 143 are not limited thereto.

Please return to FIG. 1. In the embodiment, the electronic device 100 further includes a touch display layer 150, a cover plate 155, and a metal back cover 160. The motherboard 110 is located between the metal back cover 160 and the metal shielding cover 120. The touch display layer 150 is disposed on a side of the shielding member 140 opposite to the metal shielding cover 120 and is well supported at a position corresponding to the sensing area 141 by the configuration of the support structure 143 to provide a user with a smooth usage experience of the stylus. The cover plate 155 is disposed on the touch display layer 150. The touch display layer 150, the shielding member 140, and the cover plate 155 are combined together to form a touch display.

In other words, the electronic device 100 of the embodiment is provided with the through hole 142 on the original shielding member 140 in the touch display at a position corresponding to the near field communication antenna module 130, so that contactless point-to-point data transmission may be performed through a front side of the electronic device 100 without increasing the thickness of the electronic device 100.

Through experiments, for the electronic device 100 of FIG. 1, the radiation power measured at multiple positions on the front side of the cover plate 155 at distances of between 0 mm and 5 mm from the cover plate 155 is approximately between 6.7 mW and 9.9 mW, which are all greater than the minimum radiation power of 4.68 mW in the specification, so the device has good performance.

For the device of the near field communication antenna module 130 (with four loops 136 on the first surface 132) of FIG. 3, the radiation power measured at multiple positions on the front side of the cover plate 155 at distances of between 0 mm and 5 mm from the cover plate 155 is approximately between 5.9 mW and 8.6 mW, which are all greater than the minimum radiation power of 4.68 mW in the specification, so the device has good performance.

In addition, since the electronic device 100 does not sense through a rear side, a housing on the rear side of the electronic device 100 does not need to have a hole for antenna radiation energy to pass through. The material of the housing on the rear side of the electronic device 100 may be selected according to design requirements such as appearance aesthetics, such as selecting the entire surface to be metal, so as to enhance the texture and provide more flexibility in appearance design.

In summary, in the electronic device of the disclosure, the accommodating groove recessed in the top surface is formed on the metal shielding cover for covering the motherboard, and the near field communication antenna module is disposed in the accommodating groove. Since the metal shielding cover separates the motherboard and the near field communication antenna module, the metal shielding cover may effectively shield the influence of the parts on the motherboard on the near field communication antenna module, thereby improving the performance of the near field communication antenna module. In addition, the accommodating groove of the metal shielding cover expands toward the top surface to prevent the metal shielding cover from blocking the radiation of the near field communication antenna module, thereby further improving the extent of coverage of the radiation signal of the near field communication antenna module. In addition, the shielding member is disposed on the top surface of the metal shielding cover and includes the sensing area corresponding to the near field communication antenna module. The through holes of the sensing area may allow the radiation signal of the near field communication antenna module to pass through, so as to perform contactless point-to-point data transmission. In addition, the support structure between the through holes may maintain the overall structural strength of the sensing area of the shielding member and provide good support for the touch display layer. Furthermore, since the near field communication antenna module is disposed in the accommodating groove and is lower than the top surface of the metal shielding cover, the thickness of the electronic device may be reduced and the influence of eddy current on the magnetic flux may be eliminated.

What is claimed is:

1. An electronic device, comprising:
a motherboard;
a metal shielding cover, covering one side of the motherboard and comprising a top surface away from the motherboard and an accommodating groove recessed in the top surface;
a near field communication (NFC) antenna module, disposed in the accommodating groove and connected to the motherboard; and
a shielding member, disposed on the top surface and comprising a sensing area corresponding to the near field communication antenna module, wherein the sensing area comprises a plurality of through holes and a support structure located between the through holes.

2. The electronic device according to claim 1, wherein the accommodating groove gradually expands from a side away from the top surface to a side adjacent to the top surface, and the near field communication antenna module is lower than the top surface of the metal shielding cover.

3. The electronic device according to claim 2, wherein the accommodating groove comprises a bottom surface and a plurality of inclined surfaces, an included angle θ is between any one of the inclined surfaces and a normal direction of the bottom surface, a height of the metal shielding cover is H, a width of the near field communication antenna module is W, and arctan[H/(W/2)]≤θ≤arctan[H/(W/4)].

4. The electronic device according to claim 2, wherein the accommodating groove comprises a bottom surface and a plurality of inclined surfaces, an included angle θ is between any one of the inclined surfaces and a normal direction of the bottom surface, and 10°≤θ≤30°.

5. The electronic device according to claim 1, wherein the near field communication antenna module comprises a first loop set and a second loop set located on different planes and having overlapping projections, and each of the first loop set and the second loop set comprises at least one loop.

6. The electronic device according to claim 1, wherein the near field communication antenna module comprises a plurality of loops located on a same plane.

7. The electronic device according to claim 1, wherein the support structure comprises a first connection bar and a second connection bar crossing the sensing area and interlaced with each other, and the through holes are separated by the first connection bar and the second connection bar.

8. The electronic device according to claim 7, wherein the sensing area is a rectangle, the first connection bar connects midpoints of two long sides of the rectangle, and the second connection bar connects midpoints of two short sides of the rectangle.

9. The electronic device according to claim 7, wherein the sensing area is a rectangle, the first connection bar connects two opposite endpoints of the rectangle, and the second connection bar connects other two opposite endpoints of the rectangle.

10. The electronic device according to claim 1, wherein an area of the through holes accounts for more than 90% of an area of the sensing area.

11. The electronic device according to claim 1, further comprising:
a touch display layer, disposed on the shielding member; and
a metal back cover, wherein the motherboard is located between the metal back cover and the metal shielding cover.
